(19) United States
(12) Patent Application Publication
(10) Pub. No.: US 2024/0297459 A1
(43) Pub. Date: Sep. 5, 2024

(54) CIRCUIT BOARD CONNECTING MECHANISM

(71) Applicant: Na Li, Dongguan City (CN)

(72) Inventor: Na Li, Dongguan City (CN)

(21) Appl. No.: 18/176,495

(22) Filed: Mar. 1, 2023

(51) Int. Cl. H01R 13/627; H05K 1/18

(52) U.S. Cl. CPC H01R 13/6275; H05K 1/18; H01R 12/73; H05K 2201/09063; H05K 2201/10189

(57) ABSTRACT

A circuit board connecting mechanism comprises a connector fixed to the circuit board, a fastener, a rotary latch, and an elastic element, when the rotary latch rotates against the fastener, it can be reset by the elastic element; one end of the electronic device is connected to the connector, the other end of the electronic device is pressed down to make the other end of the electronic device press the guiding slope of the buckle, forcing the rotary latch to rotate against the fastener and compress the elastic element, when the other end of the electronic device is pressed over the buckle, the rotary latch is reset by the torsion of the elastic element, making the buckle press the upper end face of the other end of the electronic device to lock the other end of the electronic device.

### BACKGROUND OF INVENTION

### Field of the Invention

The present invention relates generally to the field of electronic technology, and more particularly to a circuit board connecting mechanism.

### Description of Related Art

To connect and assemble an electronic device (e.g., M.2 Solid State Drive) with a circuit board, one end of the electronic device shall be inserted in the connector disposed on the circuit board to form electrical conduction, and the other end of the electronic device is placed on the positioning post disposed on the circuit board, and fixed to the positioning post by screws through the holes in the circuit board, so as to fasten the other end of the electronic device to the circuit board. Finally, the entire electronic device is stably assembled on the circuit board, ensuring stable electrical conduction between the electronic device and the circuit board.

The assembly method requires screw locking, the screws shall be removed for installation or removal, the operation is complicated, the assembly is slow, the efficiency is low, and the screws are small and likely to be lost in the assembly process, causing troubles to the operator.

### SUMMARY OF THE INVENTION

The purpose of the present invention is to overcome the deficiencies of the prior art and provide a circuit board connection mechanism.

In order to solve the problems of the technologies described above, the present invention adopts the following technical solutions:

A circuit board connecting mechanism comprising a connector fixed on a circuit board, a fastener, a rotary latch rotatably installed at an upper end of the fastener, and an elastic element disposed between the fastener and the rotary latch; the rotary latch can be repositioned by the elastic element after being rotated relative to the fastener; wherein the rotary latch has a protruding latch body on an upper outer side of the rotary latch, and a guiding slope provided at an upper end of the latch body; one end of an electronic device is connected to the connector, driving the other end of the electronic device to press against the guiding slope of the latch body and cause the rotary latch to rotate relative to the fastener and compress the elastic element, when the other end of the electronic device is pressed down past the latch body, the rotary latch returns to its original position through the torsional force of the elastic element, causing the latch body to engage with an upper end surface of said other end of the electronic device and lock the electronic device in place.

More preferably, wherein the rotary latch is further provided with a handle on the upper outer side of the rotary latch, and the handle extends in one piece to an upper end of the rotary latch and extends in one piece to a lower end of the rotary latch, and an operation mark is also provided on an upper end surface of the handle; the guiding slope is a twisted slope.

More preferably, wherein the rotary latch is provided with a through hole downwards along an upper end of the through hole, and the fixed member is provided with a corresponding screw hole with the through hole; a screw passes through the through hole and is screwed into the screw hole, and the rotary latch rotates relative to the fastener using the screw as a pivot, and the screw fixes the rotary latch, elastic element and fastener together to form an assembly that is detachably installed on the circuit board.

More preferably, wherein the lower end of the rotary latch is provided with a travel limiting groove, and the upper end of the fastener is provided with a slider which is positioned within the travel limiting groove; the fastener is internally provided with a mounting hole, and a metal threaded sleeve is embedded and fixedly mounted within the mounting hole, the metal threaded sleeve having the aforementioned screw hole, and the upper and lower peripheries of the metal threaded sleeve are respectively formed with vertically distributed first teeth and second teeth, and both the first teeth and the second teeth are engaged with and positioned by an inner wall of the mounting hole.

More preferably, wherein the elastic element is a torsion spring or a leaf spring; the lower end of the latch body is integrally connected with a reinforcing part, which is fixed integrally with the rotary latch, so that a locking groove is formed between a lower end face of the latch body and a side surface of the reinforcing part and the rotary fastener for locking another end of the electronic device.

More preferably, wherein the elastic element includes an elastic body and an upper positioning part formed at an upper end of the elastic body and a lower positioning part formed at a lower end of the elastic body; the elastic body is sleeved on the upper end of the fastener, the lower positioning part passes through a lower limit hole provided on the fastener, and the upper positioning part passes through an upper limit hole provided on the rotary latch.

More preferably, wherein the fastener is formed with a threaded stud at the lower end thereof; a plurality of nuts arranged in a row are fixed on the circuit board, and the fastener is spiral-fixed in any one of the nuts through the threaded stud to be fixed on the circuit board; a lower end of the threaded stud is also formed with a slick rod with guiding function, which penetrates into the nut through the slick rod.

More preferably, wherein the periphery of the nut is provided with a restraining groove, and the lower positioning part of the elastic member passes through the lower limit hole of the fastener to extend out of the lower end surface of the fastener, and can move up and down in the lower limit hole, and after the threaded stud is spiraled into place relative to the nut, the lower positioning part is embedded in the restraining groove of the nut.

More preferably, wherein one sidewall of the restraining groove is configured with an inclined guiding surface.

More preferably, wherein a layer of Mylar can be applied on top of the nut when not in use, or alternatively, the nut can be covered by a sealing cap having a first arcuate latch and a second arcuate latch symmetrically disposed at a lower end thereof, and a positioning post located adjacent to the first arcuate latch and the second arcuate latch, wherein the first arcuate latch and the second arcuate latch are latched into the nut and tightened by positioning, and the positioning post is inserted into the restraining groove arranged around the periphery of the nut.

### BRIEF DESCRIPTION OF THE DRAWINGS

FIG. 1 is an operating state diagram of the present invention;

FIG. 2 is a close-up view of Part A in FIG. 1;

FIG. 3 is a stereogram of the present invention;

FIG. 4 is a sectional view of the present invention;

FIG. 5 is a three-dimensional exploded diagram of the present invention;

FIG. 6 is a stereogram of the rotary latch in the present invention;

FIG. 7 is a stereogram of the nut in the present invention;

FIG. 8 is a stereogram of the nut in the present invention from another viewing angle;

FIG. 9 is a stereogram of the sealing cap in the present invention;

FIG. 10 is an assembly drawing of circuit board and nut, connector and electronic device.

### DETAILED DESCRIPTION OF THE INVENTION

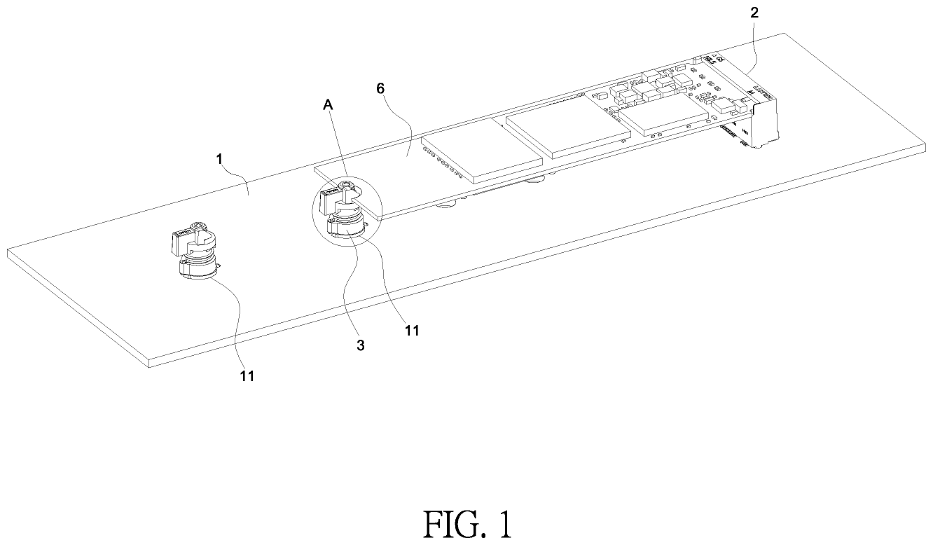

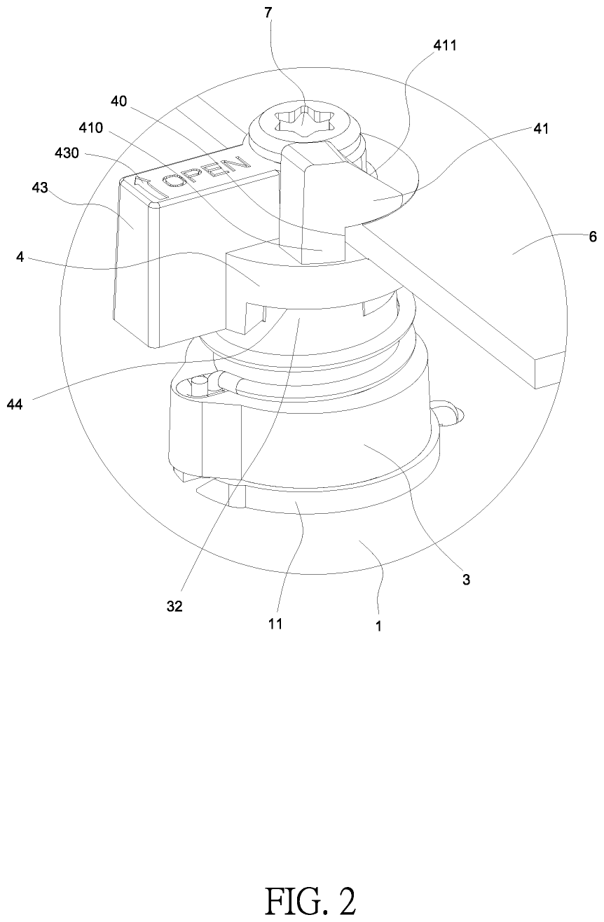

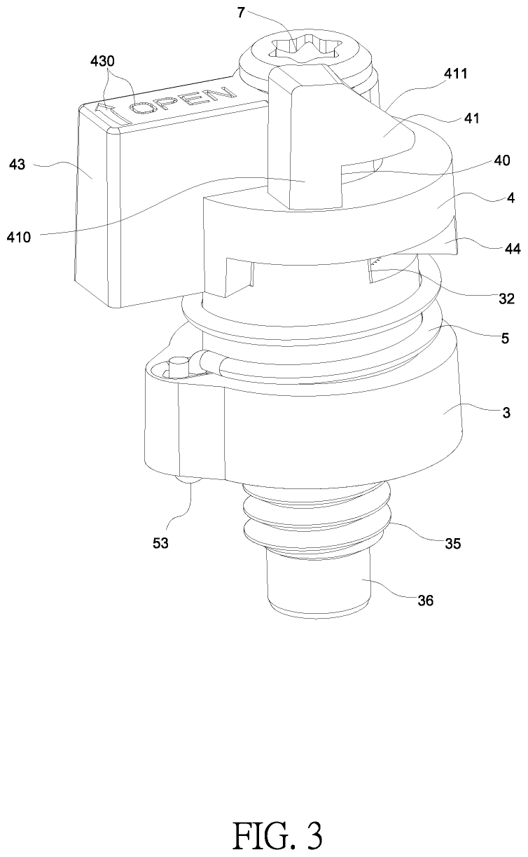

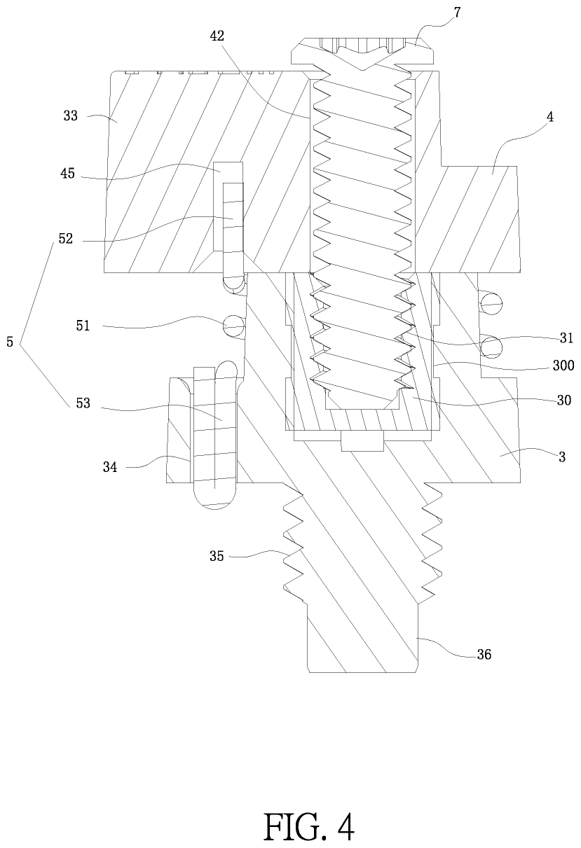

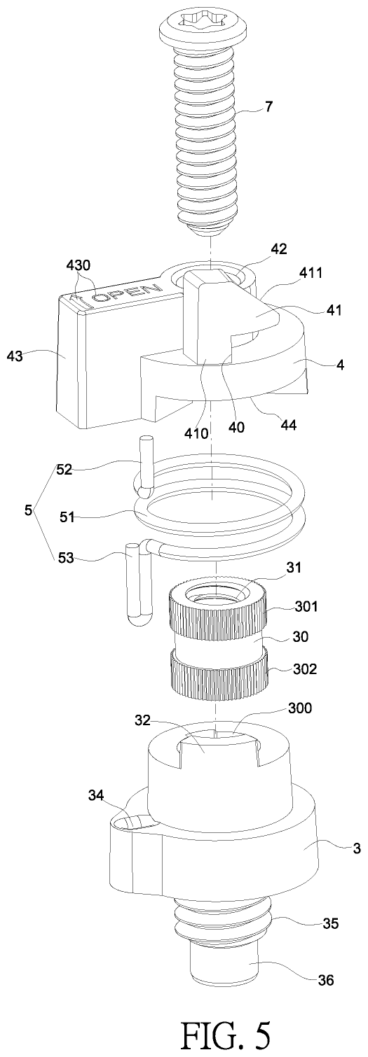

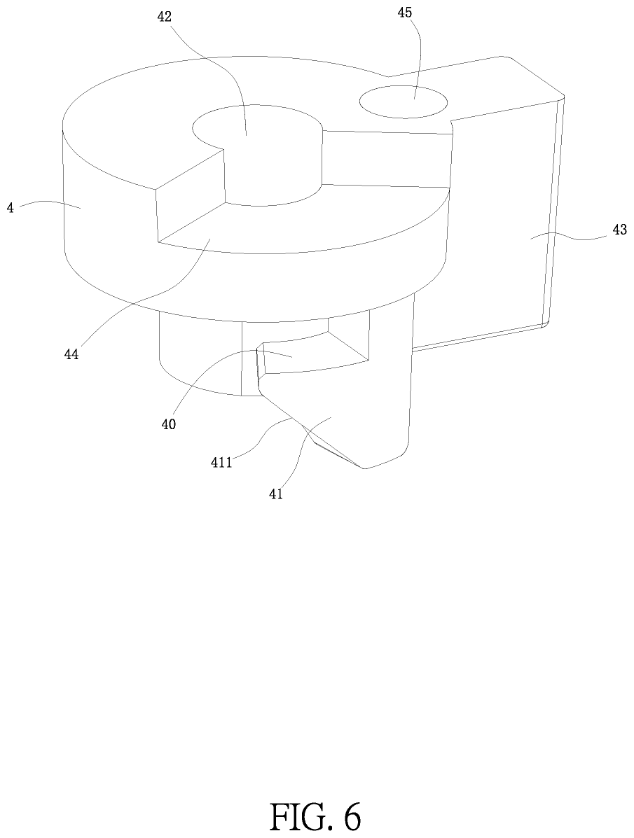

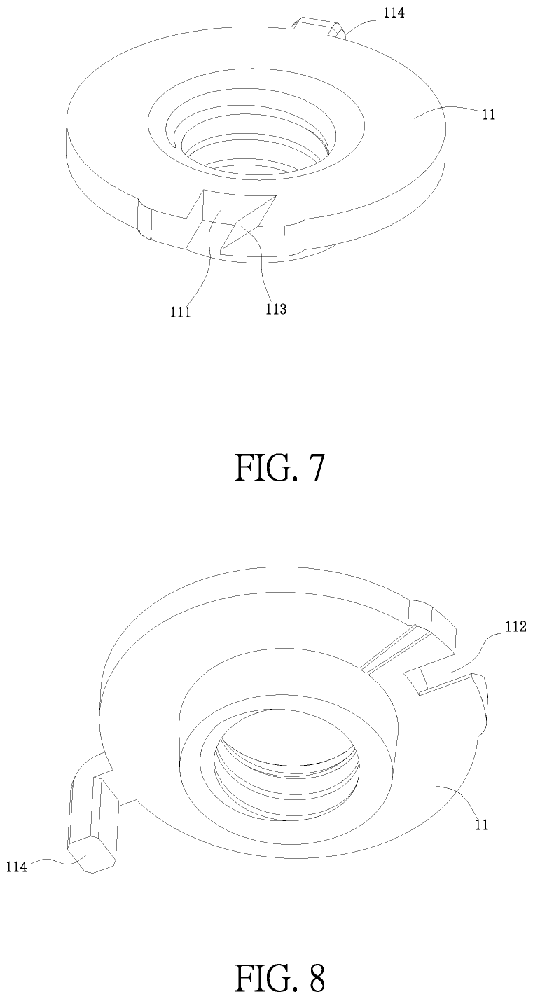

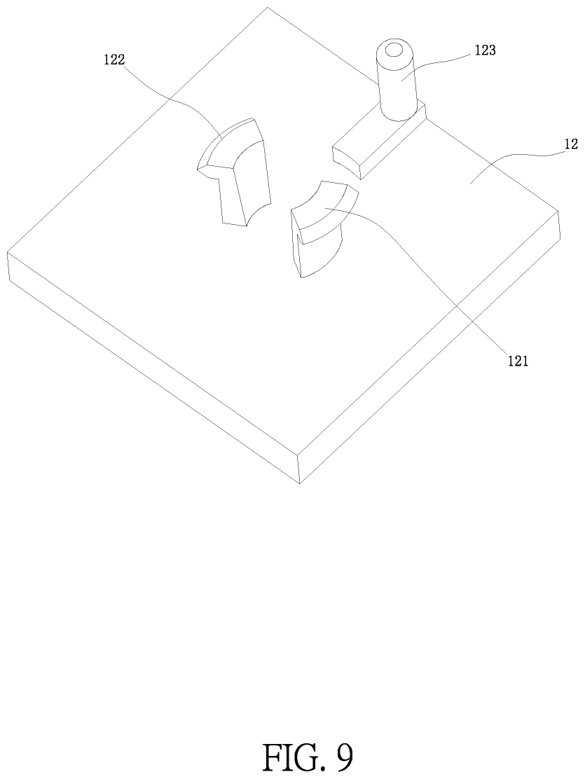

FIGS. 1-9 show a circuit board connecting mechanism, including a circuit board 1, a connector 2, a fastener 3, a rotary latch 4 and an elastic element 5.

The connector 2 is fixed to the circuit board 1 for inserting the electronic device 6, and an electrical connection is formed, so as to transmit data steadily. In this case, the electronic device 6 is an M.2 Solid State Drive, which is a Solid State Drive with an M.2 interface, and universally used in circuit boards for its small size and high-speed transmission, for example, most computers use M.2 Solid State Drive at present.

The fastener 3 is fixed to the circuit board 1 and can be removed from the circuit board 1; the rotary latch 4 is rotatably installed on the upper end of the fastener 3, the elastic element 5 is disposed between the fastener 3 and the rotary latch 4, forming steady assembly of the rotary latch 4 and fastener 3, when the rotary latch 4 is rotated against the fastener 3, the elastic element 5 is compressed, and after the rotary latch 4 is loosened, the rotary latch 4 can be reset through the elastic element 5.

A latch body 41 protruding outwards is disposed on the outer side of the upper end of the rotary latch 4, the upper end of the latch body 41 is provided with a guiding slope 411; one end of the electronic device 6 is connected to the connector 2, the other end of the electronic device 6 is pressed down to make the other end of the electronic device 6 press the guiding slope 411 of the latch body 41, forcing the rotary latch 4 to rotate against the fastener 3 and compress the elastic element 5, when the other end of the electronic device 6 is pressed over the latch body 41, automatic reset of the rotary latch 4 is implemented by the torsion of the elastic element 5, and the latch body 41 is pressed on the upper end face of the other end of the electronic device 6, the other end of the electronic device 6 is locked, so that the electronic device 6 is fixed to the circuit board 1, and stable electrical conduction is formed. In this invention, after the other end of the electronic device 6 is pressed directly, the other end of the electronic device 6 can be locked on the circuit board 1, which is convenient to operate, can be replaced quickly, and the assembly efficiency is improved. It does not need to remove screws with traditional tools such as screwdrivers, the operating time is shortened.

The lower end of the latch body 41 is integrated with a reinforcing part 410, the reinforcing part 410 and the rotary latch 4 are integrally fixed, so as to enhance the structural strength of the latch body 41, the combination of the latch body 41 and the rotary latch 4 is steadier, preventing the latch body 41 from snapping against the rotary latch 4, and a locking slot 40 for locking the other end of the electronic device 6 is formed between the lower end face of the latch body 41 and the side face of the reinforcing part 410 and the rotary latch 4, so as to lock the other end of the electronic device 6 through the locking slot 40.

The assembly method of the rotary latch 4 and the fastener 3 is as follows: a through-hole 42 is drilled downwards in the upper end of the rotary latch 4, and a screw hole 31 corresponding to the through-hole 42 is arranged in the upper end of the fastener 3, a screw 7 is fixed in the screw hole 31 through the through-hole 42, and the rotary latch 4 is rotated against the fastener 3 with the screw 7 as the rotating shaft, the screw 7 fixes the rotary latch 4, the elastic element 5 and the fastener 3 together to form an integer, the integer is installed on the circuit board 1 in a detachable way, so as to implement overall assembly and disassembly, the application is more convenient. Additionally, the upper part of the screw 7 is a slick rod, and the lower part is a thread, so that the slick rod of the screw 7 is placed in the through-hole 42, and the rotary latch 4 can rotate with the rotary latch 4 as the axle body, the lower part of the screw 7 is screwed in the screw hole 31, so that the screw 7 is fixed to the fastener 3.

The elastic element 5 provides the elastic force in the rotation direction between the rotary latch 4 and the fastener 3, so that the rotary latch 4 and the fastener 3 are assembled steadily, and the rotary latch 4, the elastic element 5 and the fastener 3 will not drop off during the vibration test.

In order to limit the rotation angle of the rotary latch 4 against the fastener 3, the following design is made: the lower end of the rotary latch 4 is provided with a travel restraining groove 44, the upper end of the fastener 3 is provided with a slider 32, the slider 32 is placed in the travel restraining groove 44, and the slider 32 only moves in the travel restraining groove 44, so as to limit the rotation angle of the rotary latch 4 against the fastener 3.

A mounting hole 300 is disposed in the fastener 3, a metal threaded sleeve 30 is fixed in the mounting hole 300, the metal threaded sleeve 30 has the screw hole 31, a first teeth 301 and a second teeth 302 distributed vertically are formed on the periphery of the upper end and the periphery of the lower end of the metal threaded sleeve 30 respectively, the first teeth 301 and the second teeth 302 are clamped and positioned with the inner wall of the mounting hole 300, so that the metal threaded sleeve 30 is steadily installed in the mounting hole 300 of the fastener 3, the spiral fixing of metal threaded sleeve 30 and screw 7 can guarantee steadier assembly structure and prevent strip.

A handle 43 is disposed on the outer side of the upper end of the rotary latch 4. To unlock the electronic device 6 which has been locked by the latch body 41, the handle 43 is pushed directly with a finger to drive the rotary latch 4 to rotate, until the latch body 41 of the rotary latch 4 leaves the other end of the electronic device 6. At this point, the other end of the electronic device 6 can be moved up to leave the rotary latch 4, so as to unlock the electronic device 6, the operation is very convenient. After the handle 43 of the rotary latch 4 is released, the rotary latch 4 is reset automatically by the torsion of the elastic element 5 to prepare for next locking.

The upper end of the handle 43 is integrally extended to the upper end of the rotary latch 4, the lower end of the handle 43 is integrally extended to the lower end of the rotary latch 4, so as to lengthen the handle 43 for the operator to rotate the rotary latch 4 conveniently.

The upper end face of the handle 43 is provided with an operation mark 430 for convenient observation and operation; the operation mark 430 includes the rotation direction arrows and an OPEN slot.

The guiding slope 411 is a twisted bevel face, which can better contact the other end of the electronic device 6, and can better implement rotation, so as to buckle the other end of the electronic device 6 to lock the other end of the electronic device 6.

The elastic element 5 includes an elastic body 51, an upper positioning part 52 formed at the upper end of the elastic body 51 and a lower positioning part 53 formed at the lower end of the elastic body 51. The elastic body 51 is fitted over the upper end of the fastener 3, the lower positioning part 53 penetrates into the lower limit hole 34 arranged in the fastener 3, and the upper positioning part 52 penetrates into the upper limit hole 45 arranged in the rotary latch 4, so that the elastic element 5 is firmly installed between the rotary latch 4 and the fastener 3.

The elastic element 5 can be a torsion spring or a spring piece, the elastic element 5 in this case is a torsion spring, which has the advantage of convenient assembly.

A threaded stud 35 is formed at the lower end of the fastener 3, the threaded stud 35 is fixed to the circuit board 1, the assembly is more convenient.

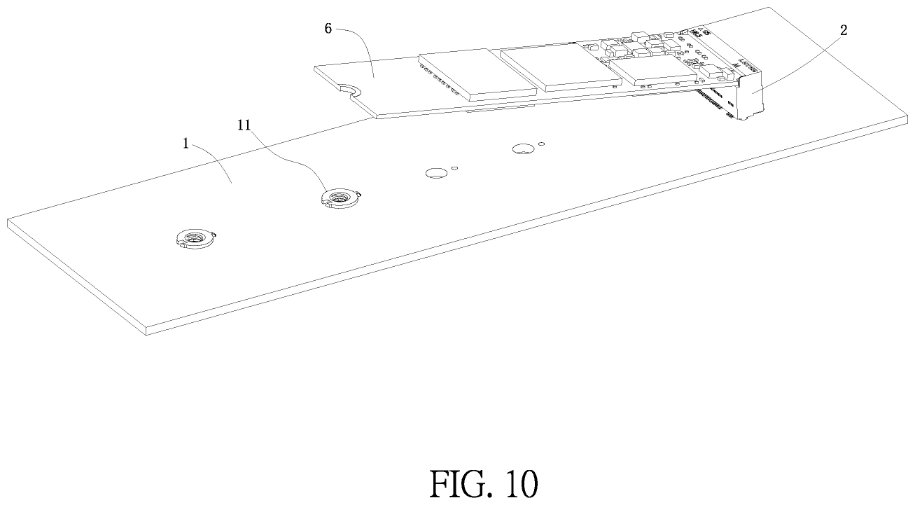

As shown in FIG. 10, to avoid the threaded stud 35 of the fastener 3 damaging the circuit board 1 in the assembly process, the following design is made: several nuts 11 distributed in a row are fixed to the circuit board 1, t the fastener 3 is screwed to any nut 11 through the threaded stud 35, so as to implement steady assembly without damaging the circuit board 1. Moreover, several nuts 11 distributed in a row are fixed to the circuit board 1, the distances between the nuts 11 and the connector 2 are different, so it can be used to lock the electronic device 6 of different sizes. Specifically, for a long electronic device 6, the nuts 11 relatively far from the connector 2 can be used, when the threaded stud 35 of the fastener 3 is spirally installed on the nut 11, the fastener 3 and the rotary latch 4 are fastened to the nut 11, and the electronic device 6 is locked by the rotary latch 4, so the present invention can lock electronic devices of different sizes, it is more applicable and more convenient.

A slick rod 36 with a guiding function is formed at the lower end of the threaded stud 35, the slick rod 36 penetrates into the nut 11, until the external thread of the threaded stud 35 can rapidly contact the internal thread of the nut 11, a threaded connection is formed, the slick rod 36 plays a guiding role in assembly, the operation is very convenient.

In addition, a restraining groove 111 is arranged on the periphery of the nut 11, the lower positioning part 53 of the elastic element 5 passes through the lower limit hole 34 of the fastener 3 to extend out of the lower end face of the fastener 3, and can move up and down in the lower limit hole 34, after the threaded stud 35 is screwed in position against the nut 11, the lower positioning part 53 is embedded in the restraining groove 111 of the nut 11. Furthermore, only a small part of the lower positioning part 53 of the elastic element 5 extends out of the lower end face of the fastener 3, in the screwing process of the threaded stud 35 against the nut 11, the lower positioning part 53 is inserted in the restraining groove 111 of the nut 11 until the threaded stud 35 is screwed in position against the nut 11, so as to guarantee the relative position of the latch body 41 on the outer side of the upper end of the rotary latch 4, and the latch body 41 is always in the position where the pressed electronic device 6 can be stopped in normal state, the pressed electronic device 6 can be pressed on the guiding slope 411 of the latch body 41.

The nut 11 not used on the circuit board 1 can be enveloped in a sealing cap 12 to prevent foreign materials or dust from entering the nut 11. Meanwhile, the sealing cap 12 can be easily sucked by the manipulator.

The lower end of the sealing cap 12 is provided with a first arcuate latch 121 and a second arcuate latch 122 distributed symmetrically and positioning posts 123 by the first arcuate latch 121 and the second arcuate latch 122, the first arcuate latch 121 and the second arcuate latch 122 are buckled into the nut 11 for tensioning and positioning, the positioning post 123 is inserted in the restraining groove 111 disposed on the periphery of the nut 11, so as to make sure the sealing cap 12 can be stably loaded on the nut 11, and to protect the internal thread of nut 11 and the external restraining groove 111.

The back side of the nut 11 is bent to form a pin 114, when the nut 11 is placed in the mounting hole of the circuit board 1, the pin 114 is inserted into the plug hole by the mounting hole on the circuit board 1 at the same time, so that the nut 11 is fixed to the circuit board 1.

In addition, one side wall of the restraining groove 111 is set as a inclined guiding surface 113, so that when the rotary latch 4, elastic element 5 and fastener 3 are integrally screwed out of the nut 11, the lower positioning part 53 of the elastic element 5 will slide out along the inclined guiding surface 113, the removal is more convenient.

Moreover, a layer of Mylar can be pasted on the unused nut 11, which can achieve the above effect of assembling the sealing cap 12.

To sum up, the present invention disposes an elastic element 5 between the rotary latch 4 and the fastener 3, a latch body 41 protruding outwards is disposed on the outer side of the upper end of the rotary latch 4, and a guiding slope 411 is disposed at the upper end of the latch body 41; in the course of operation, one end of the electronic device 6 is connected to the connector 2, and the other end of the electronic device 6 is pressed down to make the other end of the electronic device 6 press the guiding slope 411 of the latch body 41, forcing the rotary latch 4 to rotate against the fastener 3 and compress the elastic element 5 elastically, when the other end of the electronic device 6 is pressed over the latch body 41, the rotary latch 4 is reset automatically by the torsion of the elastic element 5, making the latch body 41 press the upper end face of the other end of the electronic device 6, the other end of the electronic device 6 is locked, so that the electronic device 6 is fixed to the circuit board 1, and stable electrical conduction is formed. When the other end of the electronic device 6 is pressed directly, the other end of the electronic device 6 can be locked on the circuit board 1, the operation is very convenient, quick replacement is implemented, and the assembly efficiency is increased. The screws can be removed without conventional screwdrivers, the operating time is shortened a lot.

I claim:

1. A circuit board connecting mechanism comprising
a connector (2) fixed on a circuit board (1), a fastener (3), a rotary latch (4) rotatably installed at an upper end of the fastener (3), and an elastic element (5) disposed between the fastener (3) and the rotary latch (4); the rotary latch (4) can be repositioned by the elastic element (5) after being rotated relative to the fastener (3);
wherein the rotary latch (4) has a protruding latch body (41) on an upper outer side of the rotary latch (4), and a guiding slope (411) provided at an upper end of the latch body (41); one end of an electronic device (6) is connected to the connector (2), driving the other end of the electronic device (6) to press against the guiding slope (411) of the latch body (41) and cause the rotary latch (4) to rotate relative to the fastener (3) and compress the elastic element (5),
when the other end of the electronic device (6) is pressed down past the latch body (41), the rotary latch (4) returns to its original position through the torsional force of the elastic element (5), causing the latch body (41) to engage with an upper end surface of said other end of the electronic device (6) and lock the electronic device in place.

2. The circuit board connecting mechanism according to claim 1, wherein the rotary latch (4) is further provided with a handle (43) on the upper outer side of the rotary latch (4), and the handle (43) extends in one piece to an upper end of the rotary latch (4) and extends in one piece to a lower end of the rotary latch (4), and an operation mark (430) is also provided on an upper end surface of the handle (43); the guiding slope (411) is a twisted slope.

3. The circuit board connecting mechanism according to claim 1, wherein the rotary latch (4) is provided with a through hole (42) downwards along an upper end of the through hole (42), and the fixed member (3) is provided with a corresponding screw hole (31) with the through hole (42); a screw (7) passes through the through hole (42) and is screwed into the screw hole (31), and the rotary latch (4) rotates relative to the fastener (3) using the screw (7) as a pivot, and the screw (7) fixes the rotary latch (4), elastic element (5) and fastener (3) together to form an assembly that is detachably installed on the circuit board (1).

4. The circuit board connecting mechanism according to claim 3, wherein the lower end of the rotary latch (4) is provided with a travel limiting groove (44), and the upper end of the fastener (3) is provided with a slider (32) which is positioned within the travel limiting groove (44); the fastener (3) is internally provided with a mounting hole (300), and a metal threaded sleeve (30) is embedded and fixedly mounted within the mounting hole (300), the metal threaded sleeve (30) having the aforementioned screw hole (31), and the upper and lower peripheries of the metal threaded sleeve (30) are respectively formed with vertically distributed first teeth (301) and second teeth (302), and both the first teeth (301) and the second teeth (302) are engaged with and positioned by an inner wall of the mounting hole (300).

5. The circuit board connecting mechanism according to claim 1, wherein the elastic element (5) is a torsion spring or a leaf spring; the lower end of the latch body (41) is integrally connected with a reinforcing part (410), which is fixed integrally with the rotary latch (4), so that a locking groove (40) is formed between a lower end face of the latch body (41) and a side surface of the reinforcing part (410) and the rotary fastener (4) for locking another end of the electronic device (6).

6. The circuit board connecting mechanism according to claim 5, wherein the elastic element (5) includes an elastic body (51) and an upper positioning part (52) formed at an upper end of the elastic body (51) and a lower positioning part (53) formed at a lower end of the elastic body (51); the elastic body (51) is sleeved on the upper end of the fastener (3), the lower positioning part (53) passes through a lower limit hole (34) provided on the fastener (3), and the upper positioning part (52) passes through an upper limit hole (45) provided on the rotary latch (4).

7. The circuit board connecting mechanism according to claim 1, wherein the fastener (3) is formed with a threaded stud (35) at the lower end thereof; a plurality of nuts (11) arranged in a row are fixed on the circuit board (1), and the fastener (3) is spiral-fixed in any one of the nuts (11) through the threaded stud (35) to be fixed on the circuit board (1); a lower end of the threaded stud (35) is also formed with a slick rod (36) with guiding function, which penetrates into the nut (11) through the slick rod (36).

8. The circuit board connecting mechanism according to claim 7, wherein the periphery of the nut (11) is provided with a restraining groove (111), and the lower positioning part (53) of the elastic member (5) passes through the lower limit hole (34) of the fastener (3) to extend out of the lower end surface of the fastener (3), and can move up and down in the lower limit hole (34), and after the threaded stud (35) is spiraled into place relative to the nut (11), the lower positioning part (53) is embedded in the restraining groove (111) of the nut (11).

9. The circuit board connecting mechanism according to claim 7, wherein one sidewall of the restraining groove (111) is configured with an inclined guiding surface (113).

10. The circuit board connecting mechanism according to claim 8, wherein a layer of Mylar can be applied on top of the nut (11) when not in use, or alternatively, the nut (11) can be covered by a sealing cap (12) having a first arcuate latch (121) and a second arcuate latch (122) symmetrically disposed at a lower end thereof, and a positioning post (123) located adjacent to the first arcuate latch (121) and the second arcuate latch (122), wherein the first arcuate latch (121) and the second arcuate latch (122) are latched into the nut (11) and tightened by positioning, and the positioning post (123) is inserted into the restraining groove (111) arranged around the periphery of the nut (11).
